(19) United States
(12) Patent Application Publication
(10) Pub. No.: US 2008/0254231 A1
(43) Pub. Date: Oct. 16, 2008

(54) METHOD OF FORMING PROTECTION LAYER ON CONTOUR OF WORKPIECE

(75) Inventors: Hsin Chih LIN, Banciao City (TW); Miin Jang CHEN, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: DARFON ELECTRONICS CORP.

(21) Appl. No.: 12/101,480

(22) Filed: Apr. 11, 2008

(30) Foreign Application Priority Data
Apr. 13, 2007 (TW) 096113151

(51) Int. Cl. C23C 16/513; C23C 16/22

(52) U.S. Cl. 427/576; 427/248.1

(57) ABSTRACT

The invention provides a method of forming a protection layer on a contour of a workpiece. The workpiece is made of at least one metal and/or at least one alloy. The method according to the invention forms an inorganic layer on the contour of the workpiece by an atomic layer deposition process and/or a plasma-enhanced atomic layer deposition process (or a plasma-assisted atomic layer deposition process), and the inorganic layer serves as the protection layer.

### BACKGROUND OF THE INVENTION

1. Field of the Invention

The invention relates to a method of forming a protection layer on a contour of a workpiece and, more particularly, to a method of forming a protection layer on a contour of a workpiece by an atomic layer deposition process.

2. Description of the Prior Art

Owing to environmental effects, a typical metal or alloy workpiece generally suffers from undesirable corrosion, erosion or wear, etc., such that the life of the workpiece is reduced.

In general, forming a protection layer on a contour of a workpiece can enhance properties of the workpiece, such as corrosion resistance, erosion resistance, wear resistance, fatigue resistance, and so on, so as to increase the life of the workpiece. In addition, the protection layer on the contour of the workpiece can also alter some surface properties of the contour of the workpiece, such as thermal insulation, electrical insulation, hydrophilicity, hydrophobicity, bioaffinity, surface color, and so on.

Conventionally, a manufacturer usually forms a protection layer on a contour of a workpiece by methods of plating, sputtering, hot-dipping, or the like. However, the protection layer formed by the traditional method often has the drawback of poor thickness control, insufficient conformality, or insufficient densification. Such poor quality protection layer does not help a lot in increasing the life of the workpiece.

Accordingly, a scope of the invention is to provide a method of forming a protection layer on a contour of a workpiece to solve the aforesaid problem.

### SUMMARY OF THE INVENTION

A scope of the invention is to provide a method of forming a protection layer on a contour of a workpiece. The method is to form the protection layer by an atomic layer deposition process. Thereby, the protection layer can provide excellent protection to enhance the properties of the workpiece and the life of the workpiece.

According to an embodiment of the invention, the method includes the step of forming an inorganic layer on a contour of a workpiece by an atomic layer deposition process and/or a plasma-enhanced atomic layer deposition process (or a plasma-assisted atomic layer deposition process), wherein the inorganic layer serves as the protection layer.

Therefore, the method according to the invention is to form a protection layer on a contour of a workpiece by an atomic layer deposition process. Thereby, the protection layer can provide excellent protection to enhance the properties of the workpiece such as corrosion resistance, erosion resistance, wear resistance, fatigue resistance, and so on, so as to increase the life of the workpiece. Besides, the protection layer formed by the method according to the invention can also alter some properties of the contour of the workpiece such as thermal insulation, electrical insulation, hydrophilicity, hydrophobicity, bioaffinity, surface color, and so on, so as to make the workpiece extensively applicable and more commercially valuable.

The advantage and spirit of the invention may be understood by the following recitations together with the appended drawings.

### BRIEF DESCRIPTION OF THE APPENDED DRAWINGS

FIG. 1 shows the method according to an embodiment of the invention.

FIG. 2A through 2D show a table of the composition and the precursors of the inorganic layer.

FIG. 3 shows EDS spectrum of ALD-Al₂O₃ film deposited on the Mg—Li alloy.

FIG. 4A shows a SEM micrograph of the bare Mg—Li alloy.

FIG. 4B shows the SEM micrograph of ALD-Al₂O₃ film deposited on the Mg—Li alloy.

FIG. 5 shows the potentio-dynamic polarization curves of the Mg—Li alloy.

### DETAILED DESCRIPTION OF THE INVENTION

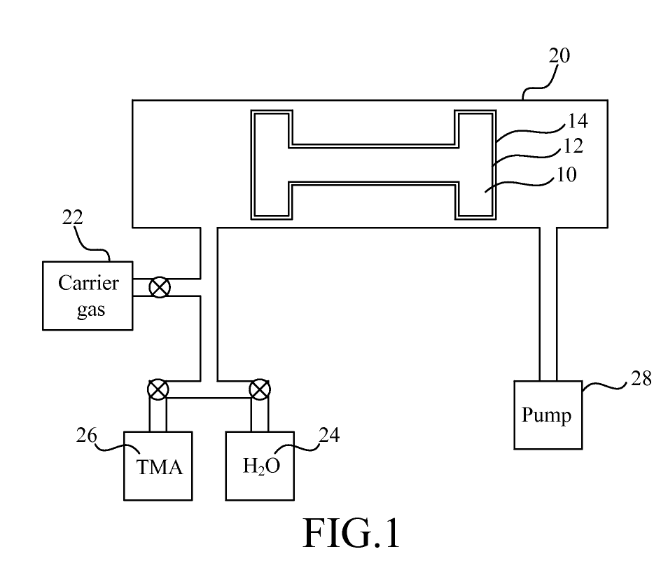

Please refer to FIG. 1. FIG. 1 shows the method according to an embodiment of the invention. The method is used for forming a protection layer on a contour 12 of a workpiece 10. The workpiece 10 can be made of at least one metal and/or at least one alloy. The metal for making the workpiece 10 can be, but not limited to, Mg, Ti, Al, Cr, Fe, Ni, Cu, Co, Pt, Pd, or Au. The alloy for making the workpiece 10 can be, but not limited to, Mg alloy, Al alloy, Ti alloy, Cr alloy, Ni alloy, Cu alloy, Co alloy, Pt alloy, Pd alloy, Fe—Ni alloy, Fe—Pt alloy, Al—Mg alloy, Mg—Li alloy, Al—Li alloy, stainless steel, TiNi alloy, TiNiCu alloy, CoCrMo alloy, TiAlV alloy, Ni-based super alloy, Co-based super alloy, or Fe—Ni-based super alloy.

As shown in FIG. 1, the workpiece 10 is set in a reaction chamber 20 designed for performing an atomic layer deposition (ALD) process.

Then, by an atomic layer deposition process, the method forms an inorganic layer 14 on the contour 12 of the workpiece 10, wherein the inorganic layer 14 serves as the protection layer of the workpiece 10. In actual applications, a plasma-enhanced atomic layer deposition process or a plasma-assisted atomic layer deposition process can be cooperated with the atomic layer deposition process to form the inorganic layer 14 on the contour 12 of the workpiece 10. Using the plasma-enhanced ALD process or the plasma-assisted ALD process can ionize precursors, so as to lower the deposition temperature and to improve the film quality. It is noticeable that the atomic layer deposition process is also named as Atomic Layer Epitaxy (ALE) process or Atomic Layer Chemical Vapor Deposition (ALCVD) process, so that these processes are actually the same.

In the embodiment, the inorganic layer 14 can be annealed at a temperature ranging from 100° C. to 1500° C. after deposition.

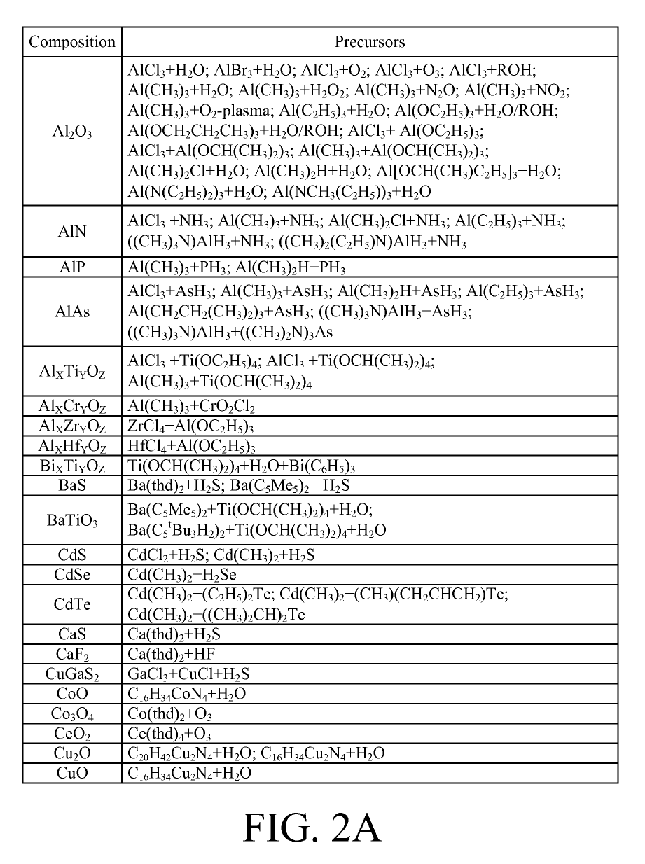

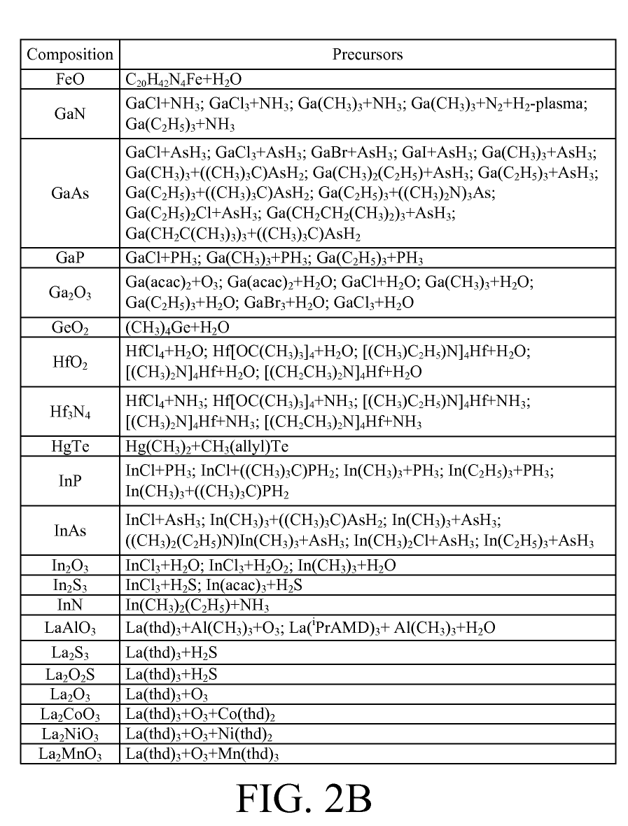

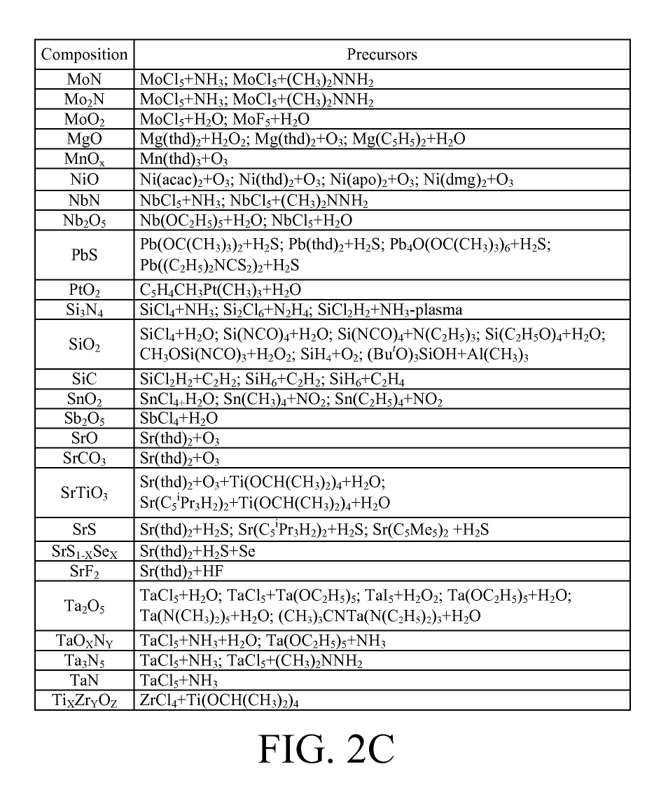

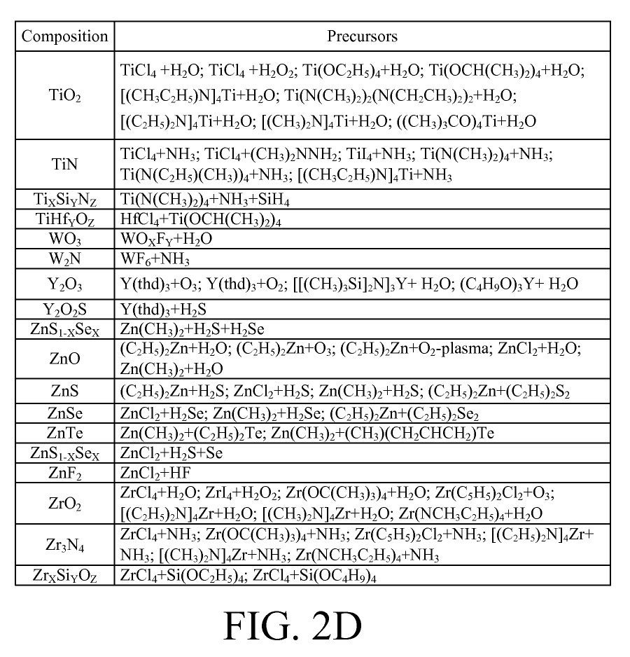

Please refer to FIGS. 2A through 2D. FIGS. 2A through 2D show a table of the composition and the precursors of the inorganic layer. In the embodiment, the composition of the inorganic layer 14 can include, but not limited to, Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Bi_{X}Ti_{Y}O_{Z}, BaS, BaTiO₃, CdS, CdSe, CdTe, CaS, CaF₂, CuGaS₂, CoO, Co₃O₄, CeO₂, Cu₂O, FeO, GaN, GaAs, GaP, Ga₂O₃, GeO₂, HfO₂, Hf₃N₄, HgTe, InP, InAs, In₂O₃, In₂S₃, InN, LaAlO₃, La₂S₃, La₂O₂S, La₂O₃, La₂CoO₃, La₂NiO₃, La₂MnO₃, MoN, Mo₂N, MoO₂, MgO, MnOₓ, NiO, NbN, Nb₂O₅, PbS, PtO₂, Si₃N₄, SiO₂, SiC, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, Ti_{X}Zr_{Y}O_{Z}, TiO₂, TiN, Ti_{X}Si_{Y}N_{Z}, TiHf_{Y}O_{Z}, WO₃, W₂N, Y₂O₃, Y₂O₂S, ZnS_{1-X}Se_{X}, ZnO, ZnS, ZnSe, ZnTe, ZnS_{1-X}Se_{X}, ZnF₂, ZrO₂, Zr_{X}Si_{Y}O_{Z}, or the like, or a mixture of above materials. The table of the composition and the precursors of the inorganic layer 14 is as shown in FIGS. 2A through 2D.

In the table shown in FIGS. 2A through 2D, thd means 2,2,6,6,-tetramethyl-3,5-heptanediode. Alkaline-earth and yttrium thd composite can include neutral adduct, or can be slightly oligomerized. In the table, acac means acetyl acetonate; ⁱPr means CH(CH₃)₂; Me means CH₃; ^{t}Bu means C(CH₃)₃; apo means 2-amino-pent-2-en-4-onato; dmg means dimethylglyoximato; (Bu^{t}O)₃SiOH means tris(tert-butoxy)silanol (((CH₃)₃CO)₃SiOH); La(ⁱPrAMD)₃ means tris(N,N′-diisopropylacetamidinato) lanthanum.

As shown in FIG. 1, an example of forming an Al₂O₃ thin film by an atomic layer deposition process is presented. In an embodiment, an atomic layer deposition cycle (ALD cycle) includes four reaction steps of:
1. Using a carrier gas 22 to carry H₂O molecules 24 into the reaction chamber 20; thereby, the H₂O molecules 24 are absorbed on the surface of the contour 12 of the workpiece 10 to form a layer of OH radicals.
2. Using the carrier gas 22, with assistance of the pump 28, to purge the H₂O molecules which are not absorbed on the surface of the contour 12 of the workpiece 10.
3. Using the carrier gas 22 to carry TMA (Trimethylaluminum) molecules 26 into the reaction chamber 20; thereby, the TMA molecules 26 react with the OH radicals absorbed on the surface of the contour 12 of the workpiece 10 to form one monolayer of Al₂O₃, where a by-product is organic molecules.
4. Using the carrier gas 22, with assistance of the pump 28, to purge the residual TMA molecules 26 and the by-product due to the reaction.

In the embodiment, the carrier gas 22 can be highly pure argon gas or nitrogen gas. The above four steps is called one ALD cycle. One ALD cycle grows a thin film with a thickness of only one monolayer on the entire surface of the contour 12 of the workpiece 10; the characteristic is named as “self-limiting”, and the characteristic allows the precision of the thickness control of the atomic layer deposition to be one monolayer. Therefore, the thickness of the protection layer can be precisely controlled by the number of ALD cycles.

In an embodiment, the deposition temperature is in a range of from room temperature to 600° C. It is noticeable that since the deposition temperature is relatively low, the damage and/or malfunction probability of equipment owing to high temperature can be reduced, and the reliability of the process and the equipment availability are further enhanced.

The inorganic layer formed by the atomic layer deposition process has following advantages:
1. Excellent conformality and good step coverage.
2. Precise thickness control, to the degree of one monolayer.
3. Low defect density and pinhole-free structures.
4. Low deposition temperatures.
5. Accurate control of material composition.
6. Abrupt interface and excellent interface quality.
7. High uniformity.
8. Good process reliability and reproducibility.
9. Large-area and large-batch capacity.

Melting of Mg-10Li-1Zn-0.3Mn alloys is processed in a high frequency electric induction furnace equipped with vacuum capability and inert argon gas is employed. The cast alloys are analyzed with ICP-AES (Induction Coupled Plasma Atomic Emission Spectrometry) apparatus, and their chemical compositions are shown in Table I below.

TABLE I

Alloy

| | Li | Zn | Mn | Si | Al | Mg |
|---|---|---|---|---|---|---|
| LZ101 | 10 | 0.52 | 0.29 | 0.04 | 37 ppm | balance |

The materials in the form of extruded plates with 10 mm thickness resulting from casting rods with diameter of 200 mm are used. Parts of the extruded plates were hot rolled to 3 mm thickness. Then specimens for various testing are carefully cut from these plates.

Al₂O₃ films are deposited on the Mg—Li alloy substrates. The samples are used for composition and thickness measurements by Energy Dispersive X-Ray Spectrometer (EDS) and α-step. The EDS measurements show only Al, O, and Mg, in ratios accordant with Al₂O₃. The α-step measurements are consonant with the deposition rate measured. In addition, Al₂O₃ films hardness and young's modulus measured by Nano-Indenter (NIP). The NIP measurement shows that reached high values of 14.17 GPa and 205.79 GPa. Meanwhile, it can also be found that the value being close to Al₂O₃ bulk. This feature is ascribed that the corrosion and wear resistance considerably had promotion.

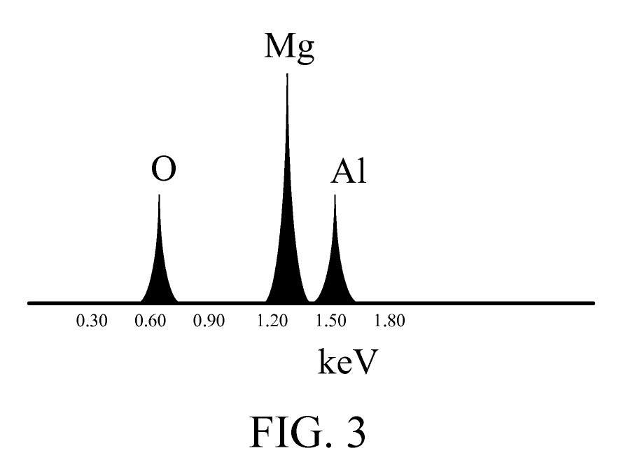

Please refer to FIG. 3. FIG. 3 shows EDS spectrum of ALD-Al₂O₃ film deposited on a Mg—Li alloy. We establish the composition of the deposited film by energy-dispersive x-ray spectrum (EDS) imaging of the films in the SEM. Results of this analysis are shown in FIG. 3, where Mg is confined to the substrate, while Al and O are confined to the area of the film. The perceived intensity ratio of Al and O in the EDS analysis is consonant with formerly measured Al₂O₃ materials, and does not vary with position on the Mg—Li alloy structure. No elements other than Al and O are perceptible in the film region. SEM imaging of the Mg—Li/Al₂O₃ interface shows the interface to be abrupt and the Al₂O₃ film to be amorphous, as expected for deposition at low temperature.

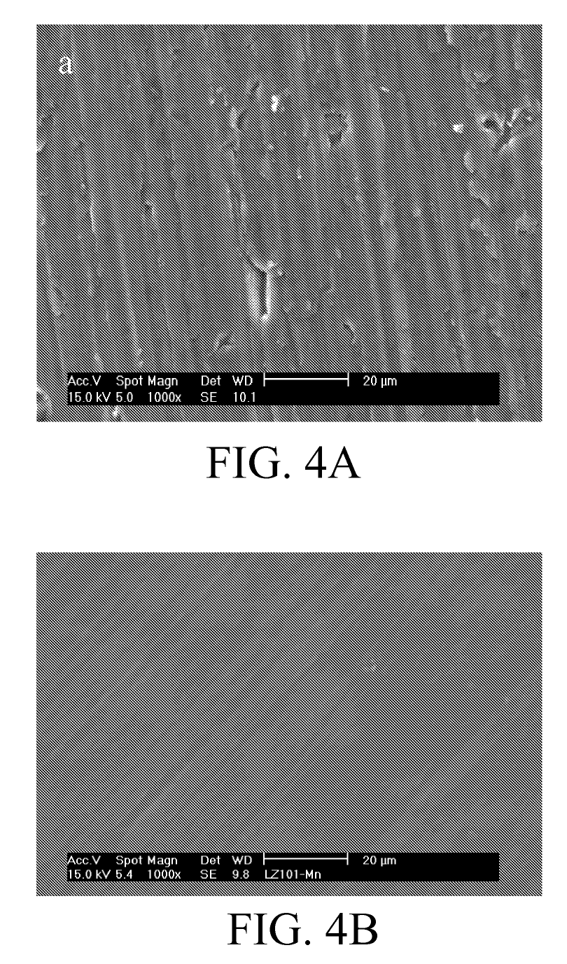

Please refer to FIG. 4A and FIG. 4B. FIG. 4A shows a SEM micrograph of the bare Mg—Li alloy. FIG. 4B shows a SEM micrograph of ALD-Al₂O₃ film deposited on the Mg—Li alloy. Experimental parameter on the ALD coating 50-150 nm of Al₂O₃ is deposited using 500-1500 cycles of TMA/H2O exposure. As shown in FIG. 4B, after deposition, the substrate is surface micrograph for SEM scrutiny. SEM analysis films are near to Mg—Li alloy surface morphology. Therefore, ALD technology has well excellent conformity.

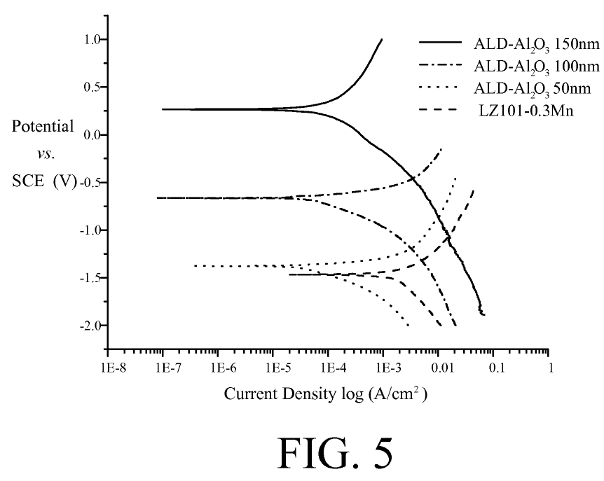

Please refer to FIG. 5. FIG. 5 shows the potentio-dynamic polarization curves of the Mg—Li alloy. All films were immersed in 3.5% NaCl with a scanning rate of 2 mV/sec. As shown in FIG. 5, the corrosion potential (E_{corr}) and the corrosion current density (I_{corr}) is determined by Tafel plot. It is found that the value of E_{corr} is strongly affected by the film thickness level. The changes of composition of Al₂O₃ thin films reflect on different E_{corr} since the E_{corr} is attributed to thermodynamic consideration. From FIG. 5, the E_{corr} reaches a maximum value from −1.46 to 0.268 mV SCE with the film thickness increasing from 50 nm˜150 nm. In addition, as shown in FIG. 5, the corrosion potentials of coating Al₂O₃ thin films on Mg—Li alloy in 3.5% NaCl solutions are higher than those of raw materials Mg—Li alloy. And the corrosion current densities of coating Al₂O₃ thin films Mg—Li alloy, on the contrary, are lower than those of raw materials Mg—Li alloy. These features indicate that the coating Al₂O₃ thin films Mg—Li alloy has a better corrosion resistance than raw materials Mg—Li alloy. Meanwhile, it can also be found that the corrosion potentials in 150 nm Al₂O₃ thin films are well highest than other process. This phenomenon can be explained as below. Due to Al₂O₃ thin films have excellent conformity, abrupt interfaces, high uniformity over large area, good reproducibility, dense and pinhole-free structures. And 150 nm Al₂O₃ films by ALD process have the best corrosion-resistant ability than those of Mg—Li alloy. Hence, surface morphology doesn't make forming galvanic corrosion; ultimately Mg alloy seriously cause corrosion failure.

Comparing with the prior art, the method according to the invention is to form a protection layer on a contour of a workpiece by an atomic layer deposition process. Thereby, the protection layer can provide excellent protection to enhance the properties of the workpiece such as corrosion resistance, erosion resistance, wear resistance, fatigue resistance, and so on, so as to increase the life of the workpiece. Besides, the protection layer formed by the method according to the invention can also alter the properties of the contour of the workpiece such as thermal insulation, insulation, hydrophilicity, hydrophobicity, bioaffinity, surface color, and so on, so as to make the workpiece extensively applicable and more commercially valuable.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of forming a protection layer on a contour of a workpiece made of at least one metal and/or at least one alloy, said method comprising the step of
by an atomic layer deposition process and/or a plasma-enhanced atomic layer deposition process, forming an inorganic layer on the contour of the workpiece, wherein the inorganic layer serves as the protection layer.

2. The method of claim 1, wherein the inorganic layer is formed at a deposition temperature ranging from room temperature to 600° C.

3. The method of claim 1, wherein the inorganic layer is further annealed at a temperature ranging from 100° C. to 1500° C. after deposition.

4. The method of claim 1, wherein the metal is one selected from a group consisting of Mg, Ti, Al, Cr, Fe, Ni, Cu, Co, Pt, Pd, and Au.

5. The method of claim 1, wherein the alloy is one selected from the group consisting of Mg alloy, Al alloy, Ti alloy, Cr alloy, Ni alloy, Cu alloy, Co alloy, Pt alloy, Pd alloy, Fe—Ni alloy, Fe—Pt alloy, Al—Mg alloy, Mg—Li alloy, Al—Li alloy, stainless steel, TiNi alloy, TiNiCu alloy, CoCrMo alloy, TiAlV alloy, Ni-based super alloy, Co-based super alloy, and Fe—Ni-based super alloy.

6. The method of claim 1, wherein the composition of the inorganic layer is one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Bi_{X}Ti_{Y}O_{Z}, BaS, BaTiO₃, CdS, CdSe, CdTe, CaS, CaF₂, CuGaS₂, CoO, Co₃O₄, CeO₂, Cu₂O, FeO, GaN, GaAs, GaP, Ga₂O₃, GeO₂, HfO₂, Hf₃N₄, HgTe, InP, InAs, In₂O₃, In₂S₃, InN, LaAlO₃, La₂S₃, La₂O₂S, La₂O₃, La₂CoO₃, La₂NiO₃, La₂MnO₃, MoN, Mo₂N, MoO₂, MgO, MnOₓ, NiO, NbN, Nb₂O₅, PbS, PtO₂, Si₃N₄, SiO₂, SiC, SnO₂, Sb₂O₅, SrO, SrCO₃, SrTiO₃, SrS SrS_{1-X}Se_{X}, SrF₂, Ta₂O₅, TaO_{X}N_{Y}, Ta₃N₅, TaN, Ti_{X}Zr_{Y}O_{Z}, TiO₂, TiN, Ti_{X}Si_{Y}N_{Z}, TiHf_{Y}O_{Z}, WO₃, W₂N, Y₂O₃, Y₂O₂S, ZnS,-xSex, ZnO, ZnS, ZnSe, ZnTe, ZnS_{1-X}Se_{X}, ZnF₂, ZrO₂, and Zr_{X}Si_{Y}O_{Z}.

7. A method of forming a protection layer on a contour of a workpiece made of a metal or an alloy, said method comprising the step of
by an atomic layer deposition process and/or a plasma-assisted atomic layer deposition process, forming an inorganic layer on the contour of the workpiece, wherein the inorganic layer serves as the protection layer.

8. The method of claim 7, wherein the inorganic layer is formed at a deposition temperature ranging from room temperature to 600° C.

9. The method of claim 7, wherein the inorganic layer is further annealed at a temperature ranging from 100° C. to 1500° C. after deposition.

10. The method of claim 7, wherein the metal is one selected from the group consisting of Mg, Ti, Al, Cr, Fe, Ni, Cu, Co, Pt, Pd, and Au.

11. The method of claim 7, wherein the alloy is one selected from the group consisting of Mg alloy, Al alloy, Ti alloy, Cr alloy, Ni alloy, Cu alloy, Co alloy, Pt alloy, Pd alloy, Fe—Ni alloy, Fe—Pt alloy, Al—Mg alloy, Mg—Li alloy, Al—Li alloy, stainless steel, TiNi alloy, TiNiCu alloy, CoCrMo alloy, TiAlV alloy, Ni-based super alloy, Co-based super alloy, and Fe—Ni-based super alloy.

12. The method of claim 7, wherein the composition of the inorganic layer is one selected from the group consisting of Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Bi_{X}Ti_{Y}O_{Z}, BaS, BaTiO₃, CdS, CdSe, CdTe, CaS, CaF₂, CuGaS₂, CoO, Co₃O₄, CeO₂, Cu₂O, FeO, GaN, GaAs, GaP, Ga₂O₃, GeO₂, HfO₂, Hf₃N₄, HgTe, InP, InAs, In₂O₃, In₂S₃, InN, LaAlO₃, La₂S₃, La₂O₂S, La₂O₃, La₂CoO₃, La₂NiO₃, La₂MnO₃, MoN, Mo₂N, MoO₂, MgO, MnOₓ, NiO, NbN, Nb₂O₅, PbS, PtO₂, Si₃N₄, SiO₂, SiC, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, Ti_{X}Zr_{Y}O_{Z}, TiO₂, TiN, Ti_{X}Si_{Y}N_{Z}, TiHf_{Y}O_{Z}, WO₃, W₂N, Y₂O₃, Y₂O₂S, ZnS_{1-X}Se_{X}, ZnO, ZnS, ZnSe, ZnTe, ZnS_{1-X}Se_{X}, ZnF₂, ZrO₂, and Zr_{X}Si_{Y}O_{Z}.
